(19) United States
(12) Patent Application Publication
(10) Pub. No.: US 2026/0229443 A1
(43) Pub. Date: Aug. 6, 2026

(54) Charged Particle Beam Device

(71) Applicant: Hitachi High-Tech Corporation, Minato-ku, Tokyo (JP)

(72) Inventors: Yuki JOKOJI, Tokyo (JP); Masahiro FUKUTA, Tokyo (JP)

(21) Appl. No.: 19/150,591

(22) PCT Filed: Mar. 29, 2023
(86) PCT No.: PCT/JP2023/012891

§ 371 Date: Jul. 24, 2025

(51) Int. Cl. H01J 37/06; H01J 37/14; H01J 37/28

(52) U.S. Cl. CPC H01J 37/06; H01J 37/14; H01J 37/28; H01J 2237/04735

(57) ABSTRACT

This charged particle beam device includes: a charged particle gun (100) that comprises a charged particle source (101); and a charged particle optical system that focuses a charged particle beam (110) from the charged particle gun (100) onto a sample, wherein: the charged particle gun (100) comprises a first electrode (102) positioned below the charged particle source (101) and an acceleration electrode (104) positioned below the first electrode (102); an optic axis is included between the first electrode (102) and the acceleration electrode (104); and an equipotential space is formed that is equipotential to the voltage of the first electrode (102) in the traveling direction of the charged particles from the charged particle source (101) or has a constant voltage difference with respect to the voltage of the first electrode (102). The charged particle optical system comprises a magnetic field lens (105) disposed so that the primary surface thereof crosses the equipotential space.

### TECHNICAL FIELD

The present disclosure relates to a charged particle beam device.

### BACKGROUND ART

A scanning electron microscope (SEM) is used, for example, in an inspection process of semiconductor manufacturing. A semiconductor device has extremely fine structures such as line patterns and holes, and if there are defects in these structures, the semiconductor device will not function normally. The SEM is suitable for inspection of the semiconductor device since the SEM enables shape observation and component analysis of a nano-order microstructure.

However, with the progress of the semiconductor device manufacturing technology in recent years, the performance required of the inspection device has also increased. Important required performance of the SEM as an inspection device is as follows. The first is high resolution corresponding to further miniaturization of the semiconductor device. Since the semiconductor device includes a pattern having a width of several to several tens of nanometers, the SEM is also required to have a high resolution of several nanometers. The second is to cope with diversification of observation conditions corresponding to a change or complication of the structure of the semiconductor device. For example, the structure of a sample has been diversified by adopting a new material or introducing a high-density stacked structure such as 3D-NAND. In the SEM, a layer from which information can be obtained changes depending on acceleration performed when implanting electrons into a sample, and a surface of the sample may be observed with a low-acceleration electron beam for a countermeasure against charging, or a structure of a deep trench may be observed with a high-acceleration electron beam. Therefore, it is necessary to enable observation with a wide range of electron beams from low acceleration to high acceleration. The third is improvement in throughput of inspection. Even if the structure of the sample is finer and denser and the number of inspection points on one sample increases, it is required to restrict the extension of the inspection time as much as possible or to shorten the inspection time. In the case of the SEM, when a scanning speed of the electron beam is increased in order to increase an imaging speed, the number of electrons implanted into the sample per pixel decreases, so that a noise component of an SEM image increases and the resolution decreases. It is necessary to increase a current amount for the electron beam in order not to reduce the resolution of the SEM image even in high-speed imaging. The fourth is stability of an inspection accuracy. In order to prevent variations in inspection results, a current emitted from the electron source needs to be stable even when the SEM is continuously operated for a long time.

In summary, the required performance described above includes high resolution, high acceleration and low acceleration, a large current, and improved current stability. However, since there are many trade-off relationships therebetween, it is very difficult to simultaneously improve a plurality of the above of the performance.

For example, there is a trade-off relationship between high resolution and a large current. In order to increase the current amount for the electron beam, it is sufficient to reduce a narrowing amount of the electron beam in the electron optical system of the SEM and irradiate the sample with as many electrons emitted from the electron source as possible. However, when the narrowing amount is reduced, the electron beam is greatly affected by an aberration of the magnetic field lens, and the resolution of the SEM image is reduced.

Magnetic field superposition is known as a method for achieving both high resolution and a large current. The magnetic field superposition is a method of arranging a magnetic field lens 105, which is used as a condenser lens in the electron optical system, and an electron source 101 close to each other. FIG. 1 schematically illustrates a state of spreading of the electron beam spreads directly below the electron source 101. Electron beams 110 and 111 indicate trajectories of the electron beam when the narrowing amounts are relatively increased and decreased, respectively.

In the case of magnetic field non-superposition, the trajectory of the electron beam greatly spreads from the electron source 101 to a primary surface position 112 where the magnetic field lens 105 acts on the electron beam. As a feature of the magnetic field lens, a magnetic field is not uniform on an optic axis and at a position away from the optic axis. Therefore, an aberration occurs between electrons passing through a center of the magnetic field lens and electrons passing from an outer side. Therefore, the influence of the aberration of the magnetic field lens 105 appears greatly particularly when the narrowing amount is reduced (at a large current, an electron beam 111a).

On the other hand, in the case of the magnetic field superposition, although the electron beam immediately after being emitted from the electron source 101 spreads as in the case of the magnetic field non-superposition, since a primary surface position 113 of the magnetic field lens 105 is close to the electron source 101, the spread of the trajectory of the electron beam at the primary surface position 113 is small. Therefore, even when the narrowing amount is small (at a large current), an electron beam 111b passes through the vicinity of the center of the magnetic field lens 105, and thus it is possible to restrict a decrease in resolution caused by changing the narrowing amount. The following can be exemplified as prior art documents that disclose magnetic field superposition.

PTL 1 discloses a structure in which a magnetic field lens is disposed to overlap a tip of a thermionic electron source in order to improve resolution. In this case, the electron source and legs of a filament wire for heating and fixing the electron source may be deformed by a magnetic force when immersed in the magnetic field. According to the disclosure of PTL 1, two sets of legs of the filament wire are provided, and polarities of the legs of the filament wire are set to be alternately reversed polarities, so that a reaction force against the magnetic force of the magnetic field lens is applied to restrict the deformation.

PTL 2 discloses a structure in which a magnetic field lens is disposed at a position of an electron source, as a countermeasure against resolution degradation due to a large current, in an electron gun that emits electrons by an electric field represented by a Schottky electron source. In this case, when a tip of the electron source is immersed in the magnetic field, the emitted electrons are deflected by the magnetic field and travel in spiral movement. Since this trajectory converges so as to be parallel to an optic axis of the electron beam, a diameter of a virtual light source calculated by back-calculating the trajectory is larger than that of the virtual light source in a case of not being immersed in the magnetic field. The increase in the diameter of the virtual light source causes the resolution degradation. According to the disclosure of PTL 2, magnetic field lenses having polarities opposite to each other are arranged above and below the electron source, and control is performed so that a magnetic field is canceled at a tip portion of the electron source. Accordingly, the electrons immediately after being emitted from the electron source travel without being deflected by the magnetic field, and are subjected to the action of the magnetic field lens directly below the electron source, so that the effect of magnetic field superposition can be maximized.

### CITATION LIST

### Patent Literature

PTL 1: US2022/0076914

PTL 2: U.S. Pat. No. 11,075,053

### SUMMARY OF INVENTION

### Technical Problem

As disclosed in the prior art documents, the magnetic field superposition has a problem that a magnetic field of a magnetic field lens brought close to a charged particle source exerts a side effect on the electron source. For example, in PTL 1, the structure prevents the deformation of the electron source due to the magnetic force, but the side effect on the trajectory of the electron directly below the electron source cannot be controlled. In PTL 2, the structure can control the trajectory of electrons directly below the electron source, but there are two major problems in implementing the structure.

First, it is very difficult to control the cancellation of the magnetic field at the tip portion of the electron source. Due to the arrangement of the two magnetic field lenses for canceling the magnetic field, the magnitude of an excitation current flowing through each coil, and the like, an error occurs in the magnetic field generated by each magnetic field lens, and it is difficult to completely cancel the magnetic field on the electron source.

Although not illustrated in FIG. 1, the electron gun includes an electrode group for emitting the electron beam from the electron source. In the case of the magnetic field non-superposition, the electrode group is arranged between the electron source 101 and the magnetic field lens 105. That is, an electrostatic lens formed by the electrode group and the magnetic field lens 105 are spatially separated from each other, and alignment of optic axes thereof (referred to as axis adjustment) can be performed by mechanical position movement or electrical deflection by a deflector. On the other hand, in the case of magnetic field superposition, at least a part of the electrode group of the electron gun is disposed above the magnetic field lens 105, and the other part is disposed below the magnetic field lens 105. That is, the electrostatic lens formed by the electrode group and the magnetic field lens 105 spatially overlap each other. Since it is essential that the optic axis of the electrostatic lens and the optic axis of the magnetic field lens align with each other in the same space, an axis adjustment means imposes restrictions. In practice, since the magnetic field lens is disposed in a region where the electrode group of the electron gun is densely disposed, a magnetic field superposition structure may have a structure in which, for example, the electrostatic lens also functions as a magnetic path. In such a case, since the electrostatic lens and the magnetic field lens are integrated, it is impossible to independently perform axis adjustment of both lenses.

Second, it is difficult to cope with an acceleration condition of the electron beam. Due to the diversity of samples, a wider range is required for the acceleration condition of the electron beam in the charged particle beam device, and for example, a high acceleration band is required for observation of a sample having a three-dimensional structure. When the acceleration condition is switched, the magnetic field lens also needs to change the excitation current according to an acceleration state of the electron beam. This is because the magnitude of the magnetic field necessary for accelerating and focusing electrons having high energy changes.

In the magnetic field superposition, electrons are accelerated, and a voltage difference changes depending on a voltage applied to the extraction electrode, so that optical system calculation for obtaining the magnitude of the necessary magnetic field becomes complicated. Further, under a high acceleration condition of the electron beam, the excitation current of the magnetic field lens also increases. There is a limit to the current that can flow through a control circuit, and if the excitation current increases, the coil will heat up. Since lens performance of the magnetic path and coil varies depending on the temperature, it takes a long time to wait for temperature stabilization when the acceleration condition widely changes. Therefore, a decrease in stability of the device and a decrease in throughput may be caused.

### Solution to Problem

A charged particle beam device according to an embodiment of the present disclosure includes a charged particle gun including a charged particle source and a charged particle optical system configured to focus a charged particle beam from the charged particle gun onto a sample. The charged particle gun includes a first electrode positioned below the charged particle source and an acceleration electrode positioned below the first electrode, and is formed with an equipotential space between the first electrode and the acceleration electrode, the equipotential space including an optic axis and being equipotential to a voltage of the first electrode in a traveling direction of charged particles from the charged particle source or having a constant voltage difference with respect to the voltage of the first electrode. The charged particle optical system includes a magnetic field lens disposed such that a primary surface thereof crosses the equipotential space.

### Advantageous Effects of Invention

Even in a charged particle beam device in which an acceleration condition greatly changes, magnetic field superposition, in which a side effect of a magnetic field lens on a charged particle source is restricted, is implemented. Other technical problems and novel features will become apparent from description of the present description and the accompanying drawings.

### BRIEF DESCRIPTION OF DRAWINGS

FIG. 1 is a diagram schematically illustrating a state of spreading of an electron beam immediately below an electron source.

FIG. 2 illustrates a configuration example of a charged particle beam device.

FIG. 3 is a graph illustrating a relationship between a distance between a tip of an electron source and a primary surface of a magnetic field lens and an aberration coefficient.

FIG. 4 is a graph illustrating a relationship between a distance between a tip of an electron source and a primary surface of a magnetic field lens and an aberration coefficient.

FIG. 5A illustrates an example in which a magnetic field lens of a top lens type is used as a first condenser lens.

FIG. 5B illustrates an example in which a magnetic field lens of a bottom lens type is used as a first condenser lens.

FIG. 6 illustrates an example in which a diaphragm for differential exhaust is provided in a cylindrical electrode.

FIG. 7 illustrates an example of using a cylindrical electrode whose diameter increases near its opening.

FIG. 8 illustrates an example in which an electron gun is provided with a magnetic field shield.

FIG. 9 is a diagram illustrating an example of a power supply configuration in an electron gun according to Embodiment 2.

FIG. 10 is a diagram illustrating an example of a configuration of an electron gun including an axis adjustment unit.

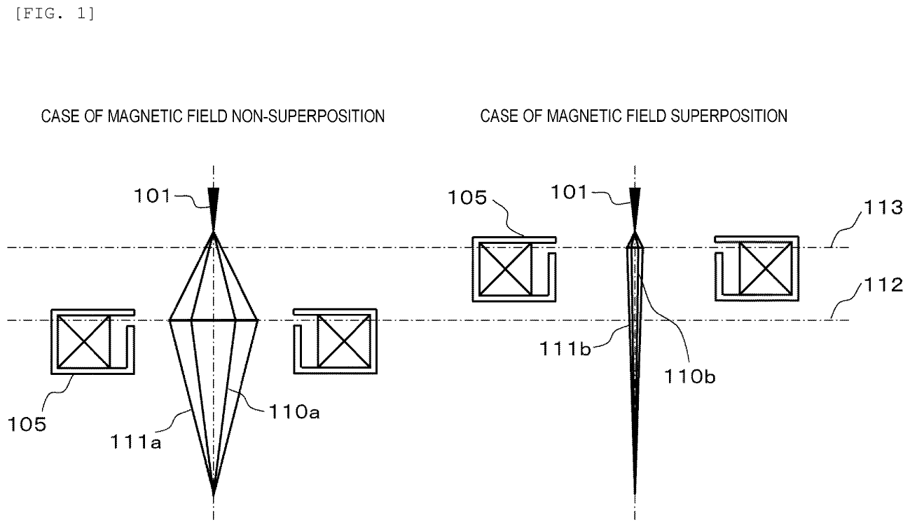

### DESCRIPTION OF EMBODIMENTS

Hereinafter, an embodiment of the present disclosure will be described with reference to the drawings.

### Embodiment 1

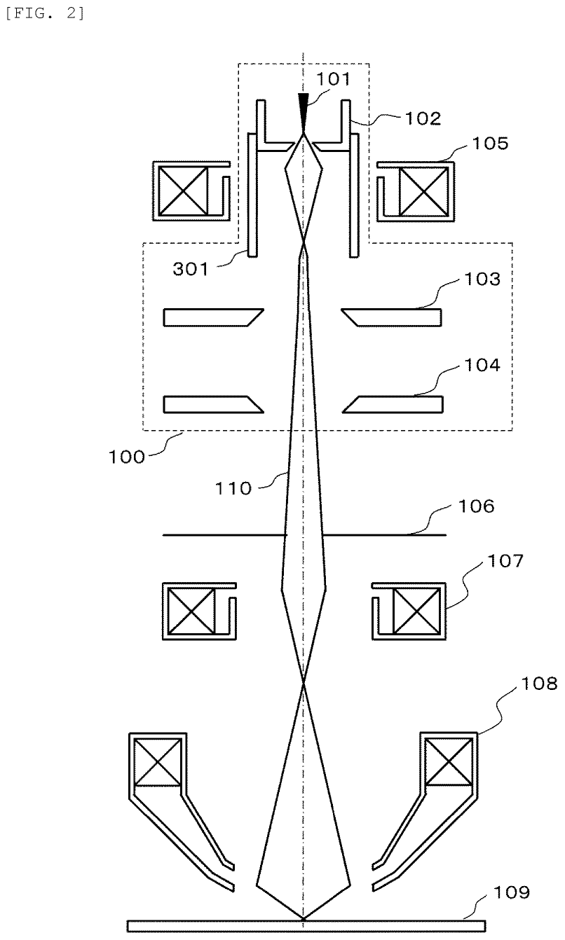

FIG. 2 illustrates a configuration example of a charged particle beam device according to Embodiment 1. FIG. 2 illustrates, as a basic configuration of an electron optical system of an SEM, a configuration for focusing an electron beam such as an electron gun and a lens, and other structures such as a deflector and an aberration corrector are not illustrated.

An electron gun 100 extracts electrons from the electron source 101 and emits the electrons as an electron beam 110. By setting the electron source 101 to negative polarity and an extraction electrode 102 to positive polarity, electrons are extracted from the electron source. The extracted electrons are accelerated by an acceleration electrode 104 and emitted as the electron beam 110. An anode electrode 103 may be provided between the extraction electrode 102 and the acceleration electrode 104. By providing such the anode electrode 103 and controlling the magnitude of an electric field between the electrodes, the spread of the electron beam 110 emitted from the electron gun 100 can be controlled. Here, although an example in which the anode electrode 103 is provided in one stage is illustrated, anode electrodes in a plurality of stages may be provided. The electron beam emitted from the electron gun 100 is controlled to be focused on a sample 109 by the first condenser lens 105, a second condenser lens 107, and an objective lens 108.

In the charged particle beam device according to the embodiment, a magnetic field superposition method is applied in order to achieve both high resolution and large currents. For this reason, the first condenser lens 105, which is normally (magnetic field non-superposition) disposed closer to the sample than is the electron gun 100, is disposed directly below the electron source 101. The electron gun 100 is provided with a cylindrical electrode 301 directly below the electron source 101. In the example in FIG. 2, the cylindrical electrode 301 is fixed to the extraction electrode 102, and the cylindrical electrode 301 and the extraction electrode 102 have the same voltage. Further, the cylindrical electrode 301 and the first condenser lens 105 have a positional relationship in which a primary surface of the first condenser lens 105 crosses the cylindrical electrode 301. Accordingly, an electrostatic lens formed by an electrode group of the electron gun 100 and a magnetic field lens of the first condenser lens 105 do not spatially overlap each other. The configuration of the electron gun 100 will be further described later.

The first condenser lens 105, the second condenser lens 107, and the objective lens 108 are magnetic field lenses. In the magnetic field lens, a coil is covered with a magnetic material serving as a magnetic path, and a gap is provided in a part of the magnetic path. When the magnetic field leaks from the gap of the magnetic path, a convex lens that deflects electrons is formed. Therefore, the primary surface of the magnetic field lens is formed at the gap position of the magnetic path.

Unlike the electrostatic lens that changes a trajectory of electrons by an electric field between electrodes, the magnetic field lens, which changes the trajectory of electrons by a magnetic field generated by flowing a current through a coil, does not require a high voltage even when greatly changing the trajectory of electrons. Therefore, a magnetic field lens is used for the condenser lens and the objective lens. A current amount of the electron beam 110 is adjusted by adjusting a strength of the convex lens of the magnetic field lens to control the amount of electrons passing through a diaphragm 106.

Hereinafter, each configuration of the electron gun 100 will be described in detail.

The electron source 101 is not particularly limited. From the viewpoint of high resolution, a Schottky electron source or a field emission source that emits electrons using an electric field is suitable.

The electrode to which the cylindrical electrode 301 is fixed is not limited to the extraction electrode 102 illustrated in FIG. 2. However, the electrode to which the cylindrical electrode 301 is fixed needs to be an electrode positioned below the electron source 101. For example, when the electron source is a Schottky electron source, a suppressor electrode is provided at a position closer to the electron source 101 than is the extraction electrode 102. The suppressor electrode is an electrode provided to suppress emission of electrons, which are emitted from a side surface or the like of the Schottky electron source, to the outside. The suppressor electrode covers the side surface of the electron source and a tip of the electron source protrudes from an opening provided in the electrode. In the embodiment, being below the electron source means being below the tip of the electron beam (closer to the sample), and the suppressor electrode does not serve as an electrode for fixing the cylindrical electrode 301. On the other hand, the cylindrical electrode 301 may be fixed to an electrode (anode electrode) downstream of the extraction electrode 102 for the reason of an electrode structure of the electron gun 100 or the like. However, since the cylindrical electrode 301 and the first condenser lens 105 are arranged in such a positional relationship that the primary surface of the first condenser lens 105 crosses the cylindrical electrode 301, when the cylindrical electrode 301 is fixed to the extraction electrode 102, the primary surface of the first condenser lens 105 can be closest to the electron source 101. Accordingly, the electrons having low energy immediately after being extracted from the electron source 101 can pass through the vicinity of a center of the magnetic field lens, and a higher magnetic field superposition effect can be obtained. In the following embodiments, unless otherwise specified, the cylindrical electrode 301 is described as an electrode provided for the extraction electrode 102.

The cylindrical electrode 301 is assembled so as to be suspended from the extraction electrode 102. The cylindrical electrode 301 has a cylindrical shape, and a length of the cylinder is preferably about 1 cm to 5 cm. It is desirable that a diameter thereof is large. Accordingly, it is possible to relax the requirement for alignment accuracy in aligning a central axis of the cylindrical electrode 301 with a central axis of the extraction electrode 102, and to relax the strength requirement for an electric field generated at a tip of the cylindrical electrode 301. In addition, alignment of the anode electrode 103 and the acceleration electrode 104 can also be performed integrally with the extraction electrode 102 and the cylindrical electrode 301. A central axis of the extraction electrode 102, the cylindrical electrode 301, the anode electrode 103, and the acceleration electrode 104 aligned with one another is an optic axis of the electrostatic lens formed by the electrode group provided in the electron gun 100.

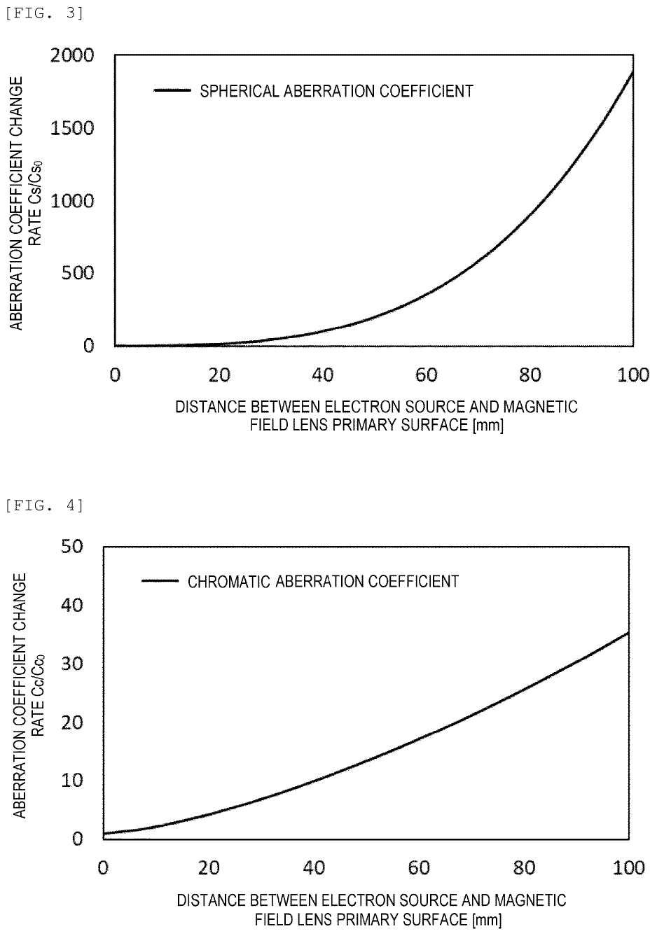

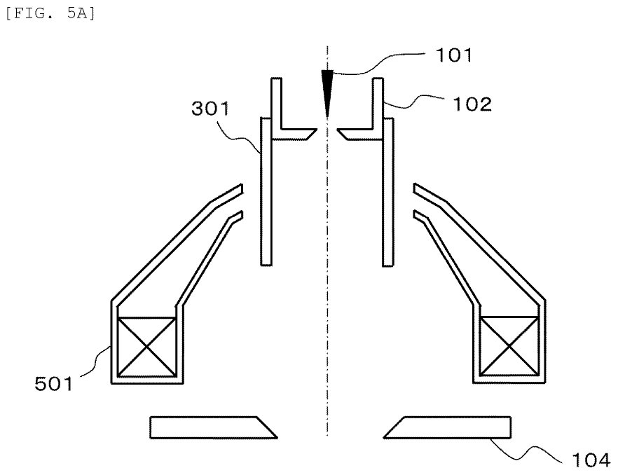

As described above, a space inside the cylinder formed by the cylindrical electrode 301 and the primary surface of the magnetic field lens 105 are arranged so as to overlap each other. Here, as a distance between the position of the primary surface of the magnetic field lens 105 and the tip of the electron source 101 is shorter, an aberration is smaller. Although major aberrations are a spherical aberration and a chromatic aberration, the spread of electrons due to spherical aberration can be expressed as (¼) Csα³, and the spread of electrons due to chromatic aberration can be expressed as (½) Ccα (ΔE/E). Here, α is a convergence angle of the electron beam, E is energy of the electron, and ΔE is a variation in the energy of the electron and is determined by a magnification of the electron source or the optical system. Cs and Cc are called a spherical aberration coefficient and a chromatic aberration coefficient, respectively, and indicate lens characteristics. The magnetic field superposition allows the electron beam to pass through the magnetic field lens with a small aberration coefficient. FIGS. 3 and 4 illustrate relationships between the distance between the tip of the electron source and the primary surface of the magnetic field lens and the aberration coefficient, which is obtained by simulation. Each horizontal axis represents the distance between the electron source 101 and the primary surface of the magnetic field lens 105, with a distance of 0 taken when the tip of the electron source 101 overlaps the primary surface of the magnetic field lens 105. Vertical axes represent change rates obtained by dividing aberration coefficients, which change according to the distance between the electron source and the primary surface of the magnetic field lens, by an aberration coefficient C₀ at the distance of 0. That is, the vertical axis in FIG. 3 represents a change rate Cs/Cs₀ of the spherical aberration coefficient, and the vertical axis in FIG. 4 represents a change rate Cc/Cc₀ of the chromatic aberration coefficient. It can be seen that, for both spherical aberration and chromatic aberration, as the distance between the tip of the electron source and the primary surface of the magnetic field lens increases, the aberration coefficient rapidly increases. However, when the distance between the tip of the electron source and the primary surface of the magnetic field lens is extremely short, the change in the aberration coefficient becomes gentle. From FIGS. 3 and 4, for example, when the distance between the tip of the electron source and the primary surface of the magnetic field lens is 25 mm or less, an effect of restricting the increase in aberration including the spherical aberration and the chromatic aberration can be obtained.

An additional process for drilled holes or the like may be performed on a side surface of the cylindrical electrode 301. A method of assembling the cylindrical electrode 301 to a fixing electrode is not limited. The cylindrical electrode 301 may be fixed by a method such as welding or cutting screw threads in a range of side surfaces of the cylindrical electrode 301 and the fixing electrode that overlap and screwing the cylindrical electrode 301 and the fixing electrode.

The extraction electrode 102 and the cylindrical electrode 301 are fixed in contact with each other, and thus are always equipotential. This means that when noise or disturbance occurs in the extraction electrode 102 due to the power supply, noise or disturbance also occurs in synchronization in the cylindrical electrode 301. Therefore, the space inside the cylindrical electrode 301 connected to the extraction electrode 102 is an equipotential space, and electrons emitted from the extraction electrode 102 travel through the equipotential space. The equipotential space formed by the cylindrical electrode 301 includes an optic axis of the electron gun 100, and no electric field is applied in a traveling direction of the electrons. Therefore, the equipotential space is not affected by the action of the electrostatic lens formed by the electrode group of the electron gun 100. By configuring the magnetic field lens to act in the equipotential space, the electrostatic lens and the magnetic field lens are spatially separated. Accordingly, as in the case of the magnetic field non-superposition, the axis adjustment of the electrostatic lens and the magnetic field lens can be independently performed.

As long as it is equipotential in the traveling direction of the electrons emitted from the electron source 101, a method of forming the equipotential space is not limited to using the cylindrical electrode 301. For example, it is also possible to form an equipotential space by disposing a plate electrode having equipotential in the traveling direction of the electrons. However, since a large number of other electrodes and deflectors are arranged in the charged particle beam device, there is a high possibility of receiving various types of noise, and it is preferable to form the inside of the cylindrical electrode having a side wall of a predetermined length along the optic axis as an equipotential space from the viewpoint of noise resistance.

In order to form the magnetic field lens at the position the cylindrical electrode 301, the material of the cylindrical electrode 301 is a non-magnetic metal such as SUS or phosphor bronze. On the other hand, since the electron source 101 and the magnetic field lens 105 are disposed close to each other, it is necessary to take measures against leakage of the magnetic field from the magnetic field lens 105 to the electron source 101. Therefore, the material of the electrode to which the cylindrical electrode 301 is fixed, that is, the material of the extraction electrode 102 is a magnetic material such as permalloy or permendur. Accordingly, the electrode to which the cylindrical electrode 301 is fixed has a function of a magnetic field shield, and it is possible to reduce the distance between the electron source 101 and the first condenser lens 105 while restricting the leakage of the magnetic field from the magnetic field lens 105.

According to the configuration of Embodiment 1, since the magnetic field lens acts on the electrons emitted to the equipotential space in the cylindrical electrode 301, the sensitivity at which the electrons are focused by the magnetic field lens is determined by the energy of the electrons emitted to the equipotential space, that is, conditions of the extraction electrode 102 in the configuration of FIG. 2, and is not affected by conditions of the anode electrode 103 and the acceleration electrode 104 positioned below the cylindrical electrode 301. This means that the strength of the magnetic field lens for focusing the electrons in the equipotential space does not change regardless of whether the electron gun 100 emits the electron beam under a high acceleration condition or emits the electron beam under a low acceleration condition. Therefore, a magnetic field lens of a small coil with a relatively small excitation current can be used as the first condenser lens 105. Since the excitation current of the first condenser lens 105 is small, a temperature rise due to heat generation of the coil caused by the excitation current is restricted to about 10° C., and the temperature does not rise far above room temperature, so that a fluctuation in performance of the magnetic field lens 105 due to a temporal change of the temperature can also be restricted.

### Modification 1

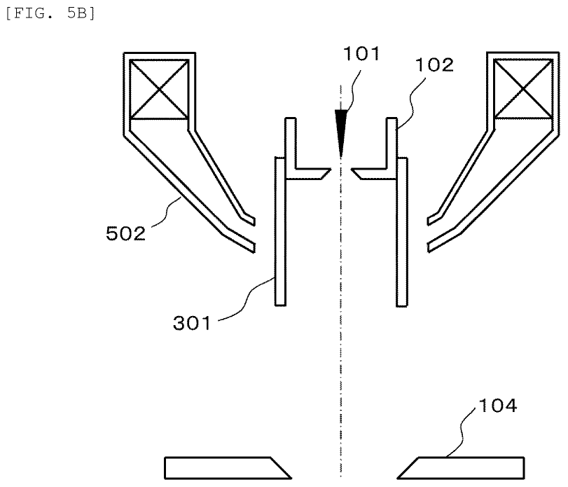

FIGS. 5A and 5B illustrate examples in which magnetic field lenses shaped to have an extended magnetic path are adopted as the first condenser lens 105 illustrated in FIG. 2. In the configuration in FIG. 2, the coil of the magnetic field lens 105, the cylindrical electrode 301, and the lens primary surface are located at the same position. For this reason, a space for accommodating the coil is required in the vicinity of the electron source 101 at an uppermost portion of a housing accommodating the electron optical system. Accordingly, a structure around the electron source 101 is huge, and a center of gravity of the housing also moves upward, so that it can be said that the structure is weak against vibration as compared with a housing that accommodates an electron optical system of magnetic field non-superposition.

In the modification, by extending the magnetic path of the magnetic field lens, a gap of the magnetic path is disposed to cross the cylindrical electrode 301, and the position of the coil is changed so as to increase the resistance to vibration. FIG. 5A is an example in which a magnetic field lens 501 of a top lens type that forms a lens above a coil is applied as the first condenser lens 105. By disposing the coil at a lower position, a lens primary surface can be brought closer to the electron source 101 while maintaining the center of gravity at a lower position. Without being limited to the example in FIG. 5A, a positional relationship with the acceleration electrode 104 and other configurations can also be changed.

FIG. 5B is an example in which a magnetic field lens 502 of a bottom lens type that forms a lens below a coil is applied as the first condenser lens 105. In general, in the electron gun 100, the electrodes are densely arranged and it is difficult to accommodate the coil, whereas a space for accommodating the coil is easily secured above the electron source. For the same reason, it is easy to add an axis adjustment mechanism above the electron source. Since the center of gravity moves upward as described above, measures against vibration are taken, such as erecting a support for damping.

In addition, in the magnetic field lens, a resin may be used in a coil portion, and it is not preferable to set a high temperature exceeding 200° C. However, the periphery of the electron source is baked at a high temperature to increase the degree of vacuum, and some portions reach about 300° C. Therefore, by increasing the distance between the primary surface of the magnetic field lens and the coil as in the modification, the influence of baking of the electron source can be avoided.

As described above, in modification 1, the position of the coil of the magnetic field lens of the first condenser lens 105 can be selected at any position, thereby avoiding a risk in design.

### Modification 2

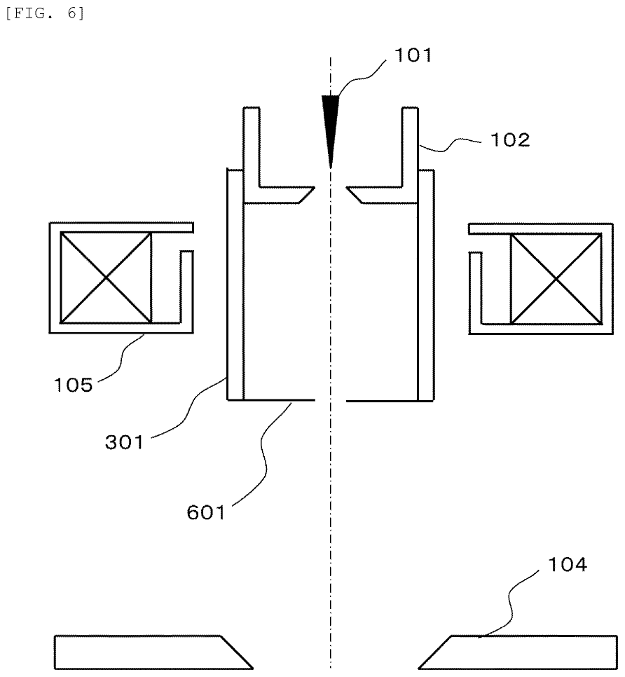

FIG. 6 illustrates an example as modification 2 in which a differential exhaust diaphragm 601 is provided at the cylindrical electrode 301. When the cylindrical electrode 301 has a simple cylindrical shape as in FIG. 2, the degree of vacuum in the space directly below the extraction electrode 102 is equal to that in the space around the acceleration electrode 104. However, it is desirable that the space between the extraction electrode 102 and the cylindrical electrode 301, which is a space that is close to the electron source 101 and through which low-energy electrons pass, has a high degree of vacuum. Therefore, as in modification 2, the differential exhaust diaphragm 601 having a small diameter is attached to an opening of the cylindrical electrode 301. The differential exhaust diaphragm 601 can maintain a high degree of vacuum by performing a differential exhaust function of reducing conductance for exhausting from the cylindrical electrode 301 to the acceleration electrode 104 side. Further, gas molecules blown up from below can be shielded to prevent gas adsorption of the electron source 101. The material of the differential exhaust diaphragm 601 is a non-magnetic metal such as SUS or phosphor bronze.

As described above, in modification 2, by adding the differential exhaust diaphragm 601 to the opening of the cylindrical electrode 301, the degree of vacuum in the vicinity of the electron source can be maintained and contamination of the electron source can be restricted.

### Modification 3

The cylindrical electrode 301 forms, directly below the electron source 101, an equipotential space having the equipotential as the electrode to which the cylindrical electrode 301 is fixed (for example, the extraction electrode 102 in the example in FIG. 2). Accordingly, a distance for accelerating the electrons from the extraction electrode 102 to the acceleration electrode 104 is shortened by the insertion of the cylindrical electrode 301. This means that a gradient of the electric field between the cylindrical electrode 301 and the acceleration electrode 104 is increased to generate a strong electrostatic lens. Therefore, when the electron beam is emitted under a high acceleration condition, there is a risk that the electrostatic lens cannot be controlled. For example, a trajectory of electrons may be bent at an angle more than necessary in the vicinity of an end of the electrostatic lens, that is, in the vicinity of an opening side wall of the cylindrical electrode 301 on the acceleration electrode 104 side, and the electrons may be focused.

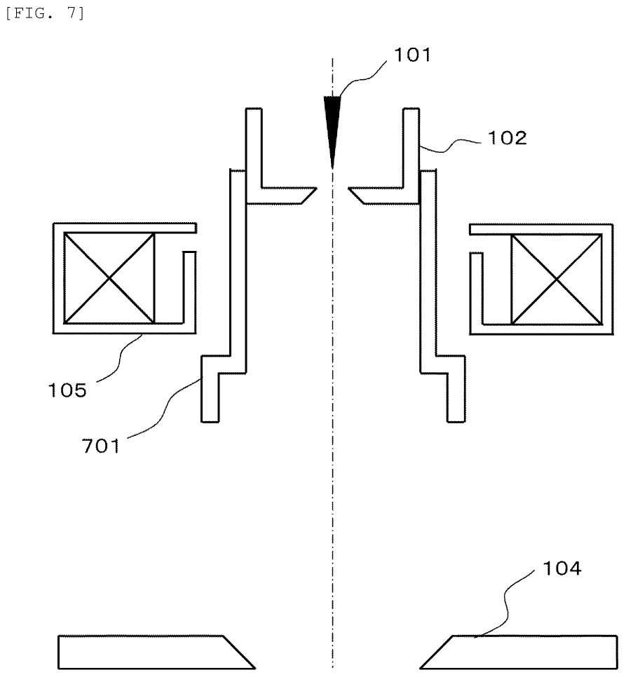

In order to avoid such an undesirable change in the trajectory of electrons, in modification 3, the cylindrical electrode is changed from the simple cylindrical shape. A cylindrical electrode 701 illustrated in FIG. 7 has a protruding shape in which a diameter thereof is increased in the vicinity of an opening on the acceleration electrode 104 side. By making the opening of the cylindrical electrode 701 on the acceleration electrode 104 side as large as possible, a focusing force of the electrostatic lens can be reduced. FIG. 7 illustrates an example in which the diameter of the cylindrical electrode is increased in two stages in an optic axis direction, and the diameter may be increased stepwise in three or more stages, or the diameter of the cylindrical electrode may be continuously increased.

As described above, in modification 3, by increasing the diameter of the opening of the cylindrical electrode on the acceleration electrode 104 side, the strength of the electrostatic lens generated in the vicinity of the opening of the cylindrical electrode can be reduced.

### Modification 4

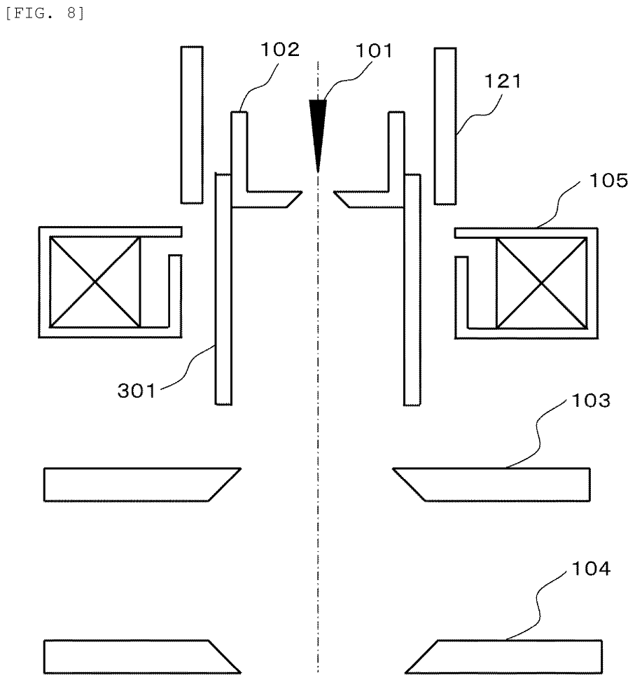

FIG. 8 illustrates an example as modification 4 in which a magnetic field shield 121 is provided in the electron gun 100. In Embodiment 1, the example is illustrated in which the electrode (the extraction electrode 102 in the example in FIG. 2) to which the cylindrical electrode 301 is fixed is made of a magnetic material so that the magnetic field from the magnetic field lens 105 does not leak to the electron source 101. In this case, there is a risk that a magnetic field gathers at an opening of the extraction electrode 102 to form a magnetic field lens.

Therefore, in FIG. 8, the material of the extraction electrode 102 is a non-magnetic material, and the magnetic field shield 121 is provided at an outer periphery of the extraction electrode 102. The magnetic field shield 121 is made of a magnetic material and is disposed to hide a side wall of the extraction electrode 102 from the magnetic field lens. For example, the cylindrical magnetic field shield 121 is installed at the same height as the extraction electrode 102. A lower end of the magnetic field shield 121 preferably reaches a position covering a portion where the extraction electrode 102 and the cylindrical electrode 301 overlap.

As described above, in modification 4, the magnetic field shield can restrict the generation of the magnetic field lens at the opening of the electrode to which the cylindrical electrode is fixed, and can prevent the magnetic field from leaking to the electron source.

### Embodiment 2

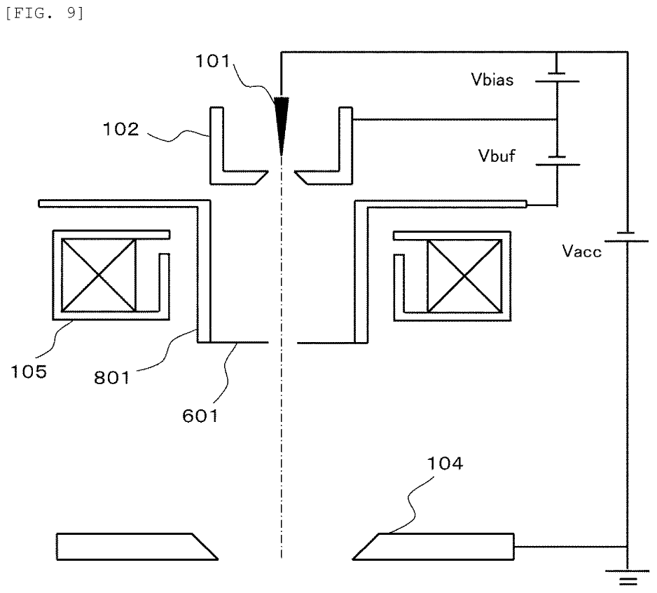

In Embodiment 1, the cylindrical electrode 301 and the electrode (for example, the extraction electrode 102) positioned below the electron source are fixed and electrically connected to each other, so that the cylindrical electrode 301 and the electrode are set to the equipotential. However, as described above, there is a risk that the electrostatic lens directly below the cylindrical electrode 301 is strong. Therefore, in Embodiment 2, the voltage of the equipotential space has a constant voltage difference with respect to the voltage of the extraction electrode 102. FIG. 9 illustrates an example of a power supply configuration in an electron gun according to Embodiment 2. As illustrated in FIG. 9, a buffer voltage Vbuf is applied to a cylindrical electrode 801 with reference to a voltage Vbias of the extraction electrode 102. That is, since the voltage of the cylindrical electrode 801 is higher than that of the extraction electrode 102 by the buffer voltage Vbuf, a voltage difference between the cylindrical electrode 801 and the acceleration electrode 104 to which a voltage Vacc is applied is smaller than that in the configuration of Embodiment 1, and a strength of the electrostatic lens directly below the cylindrical electrode 801 can be relaxed. Although the differential exhaust diaphragm 601 is provided as in modification 2, the differential exhaust diaphragm 601 may not be provided.

Since the buffer voltage Vbuf is applied to the cylindrical electrode 801 with reference to the voltage Vbias of the extraction electrode 102, even if observation conditions such as the acceleration voltage Vacc and the extraction voltage Vbias are changed after the voltage Vbuf is set, the voltage difference between the extraction electrode 102 and the cylindrical electrode 801 is maintained at the buffer voltage Vbuf regardless of the observation conditions.

As described above, in Embodiment 2, by applying the buffer voltage to the cylindrical electrode, the voltage difference between the cylindrical electrode and the acceleration electrode can be made smaller than that in Embodiment 1, and the strength of the electrostatic lens directly below the cylindrical electrode 801 can be relaxed.

### Embodiment 3

Embodiment 3 relates to an axis adjustment mechanism. An electrode structure may be that in either Embodiment 1 or Embodiment 2. In Embodiment 1, the example in which the cylindrical electrode 301 is assembled so as to be suspended from the extraction electrode 102 has been described, but in this case, axis adjustment between the extraction electrode 102 and the cylindrical electrode 301 is impossible after the assembly, and the voltage of the equipotential space inevitably is the voltage of the extraction electrode 102. According to a configuration of an axis adjustment unit described below, axis adjustment between the extraction electrode 102 and the cylindrical electrode 301 can be performed after assembly, and the voltage of the equipotential space as illustrated in Embodiment 2 can be made different from the voltage of the extraction electrode 102.

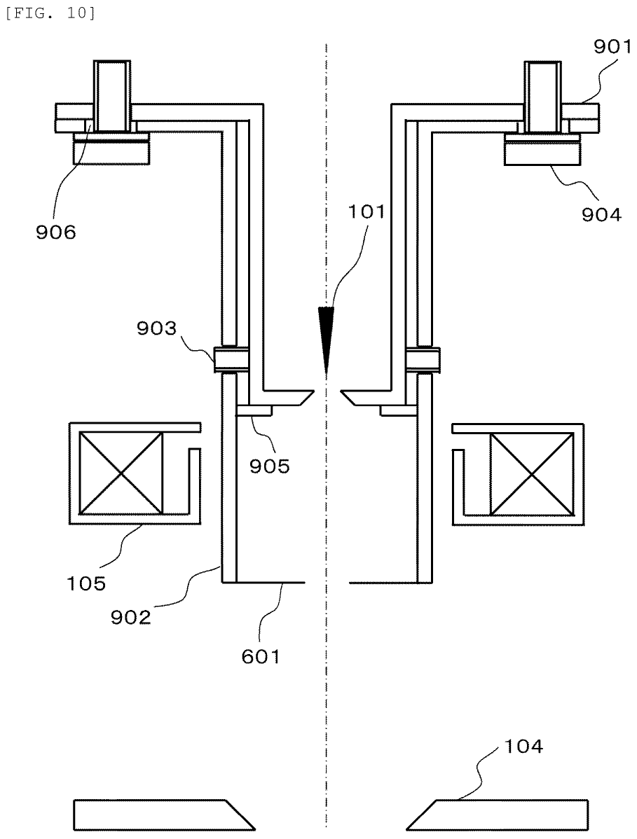

FIG. 10 illustrates a configuration of an electron gun including an axis adjustment unit in the case of the electrode structure in Embodiment 1. A first electrode 901 is, for example, an extraction electrode, and a second electrode 902 is a cylindrical electrode. A stopper 905 that supports the first electrode 901 is provided on an inner wall of the second electrode 902. Here, an example in which the differential exhaust diaphragm 601 is provided at an opening of the second electrode 902 is illustrated. The electron source 101, the first electrode 901, and the second electrode 902 are integrated as an axis adjustment unit.

When assembling the axis adjustment unit, the first electrode 901 and the second electrode 902 are attached in this order to the electron source 101 in a vertically inverted state from a state when mounted on the charged particle beam device. Fixing to the charged particle beam device is performed by passing a fixing screw 904 through drilled holes provided in both electrodes and fixing to a housing. Here, a drilled hole 906 provided in the second electrode 902 is a drilled hole having a margin so that the second electrode 902 can be moved in a horizontal direction.

A screw hole is provided in a side wall of the second electrode 902 (a side wall above the stopper 905 when mounted on the charged particle beam device). An axis adjustment screw 903 is inserted into the screw hole of the second electrode 902, and a tip of the axis adjustment screw 903 is in contact with the first electrode 901.

First, temporary assembly is performed in a state where the screw is not tightened, and then the axis adjustment screw 903 is pushed toward the first electrode 901 to move the position of the second electrode 902 with respect to the first electrode 901 (axis adjustment). After the axis adjustment, the electron source 101, the first electrode 901, the second electrode 902, and the differential exhaust diaphragm 601 can be subjected to axis adjustment by screwing the fixing screw 904. This unit is combined with the magnetic field lens 105, the acceleration electrode 104, and the like.

When adopting the electrode structure in Embodiment 2, an insulator may be provided between the first electrode 901 and the second electrode 902 so that the first electrode 901 and the second electrode 902 are not in contact with each other, and the first electrode 901 and the second electrode 902 are not in electrical contact with each other. Accordingly, when adopting the electrode structure in Embodiment 2, the electron source 101, the first electrode 901, and the second electrode 902 can also be integrated as an axis adjustment unit.

The present disclosure is not limited to the embodiments and modifications described above and includes various modifications. For example, the embodiments and modifications described above have been described in detail to facilitate understanding of the present disclosure, and the present disclosure is not necessarily limited to those including all the configurations described above. A part of the configurations of one embodiment and one modification may be replaced with configurations of other embodiments and modifications. The configurations of one embodiment and one modification may be added to configurations of other embodiments and modifications. A part of a configuration in each of the embodiments and the modifications may be added, deleted, or replaced.

Although the inspection of a semiconductor device has been exemplified as an application of the SEM, there is a similar problem in the application of analysis used in universities or research facilities. In the field of analysis, the diversity of samples increases as in the observation of organisms as compared with the inspection of semiconductor devices. The demand for continuous operation is not high, but instead, resolution, large currents, and wide acceleration conditions are important. Therefore, the present disclosure is generally useful for a charged particle beam device including a charged particle optical system that includes a charged particle gun including an electron source and a magnetic field lens.

### REFERENCE SIGNS LIST

101: electron source
102: extraction electrode
103: anode electrode
104: acceleration electrode
105: magnetic field lens (first condenser lens)
106: diaphragm
107: magnetic field lens (second condenser lens)
108: objective lens
109: sample
110: electron beam (generated with small current)
111: electron beam (generated with large current)
112: primary surface position (at time of magnetic field non-superposition)
113: primary surface position (at time of magnetic field superposition)
121: magnetic field shield
301, 701, 801: cylindrical electrode
501: magnetic field lens of top lens type
502: magnetic field lens of bottom lens type
601: differential exhaust diaphragm
901: first electrode
902: second electrode
903: axis adjustment screw
904: fixing screw
905: stopper
906: drilled hole

1. A charged particle beam device comprising:
a charged particle gun including a charged particle source; and
a charged particle optical system configured to focus a charged particle beam from the charged particle gun onto a sample, wherein
the charged particle gun includes a first electrode positioned below the charged particle source and an acceleration electrode positioned below the first electrode, and is formed with an equipotential space between the first electrode and the acceleration electrode, the equipotential space including an optic axis and being equipotential to a voltage of the first electrode in a traveling direction of charged particles from the charged particle source or having a constant voltage difference with respect to the voltage of the first electrode, and
the charged particle optical system includes a magnetic field lens disposed such that a primary surface thereof crosses the equipotential space.

2. The charged particle beam device according to claim 1, wherein
the first electrode is an extraction electrode that extracts charged particles from the charged particle source, and
the equipotential space is formed inside a cylindrical electrode having a side wall extending in an optic axis direction.

3. The charged particle beam device according to claim 2, wherein
a material of the extraction electrode is a magnetic material, and a material of the cylindrical electrode is a non-magnetic material.

4. The charged particle beam device according to claim 2, wherein
the cylindrical electrode is electrically connected to the extraction electrode.

5. The charged particle beam device according to claim 2, wherein
a predetermined buffer voltage is applied to the cylindrical electrode with reference to the voltage of the extraction electrode.

6. The charged particle beam device according to claim 1, wherein
the magnetic field lens is a magnetic field lens of a top lens type including a coil at a position lower than the primary surface or a magnetic field lens of a bottom lens type including a coil at a position higher than the primary surface.

7. The charged particle beam device according to claim 2, wherein
the cylindrical electrode includes a differential exhaust diaphragm at an opening on an acceleration electrode side.

8. The charged particle beam device according to claim 2, wherein
the cylindrical electrode has a large diameter at an opening on an acceleration electrode side.

9. The charged particle beam device according to claim 2, wherein
the charged particle gun includes a magnetic field shield surrounding an outer periphery of the extraction electrode, and
a lower end of the magnetic field shield has a height covering a portion where the extraction electrode and the cylindrical electrode overlap each other.

10. A charged particle beam device comprising:
a charged particle gun including a charged particle source; and
a charged particle optical system configured to focus a charged particle beam from the charged particle gun onto a sample, wherein
the charged particle gun includes an axis adjustment unit in which the charged particle source, a first electrode, and a second electrode are integrated, and an acceleration electrode,
a stopper is provided on a cylindrical inner wall of the second electrode, and the first electrode is supported on the stopper,
an axis adjustment screw comes into contact with the first electrode through a screw hole provided in the side wall of the second electrode above the stopper, and
the charged particle optical system includes a magnetic field lens disposed such that a primary surface thereof crosses the second electrode at a position below the stopper.

11. The charged particle beam device according to claim 10, wherein
the first electrode and the second electrode are electrically connected or the first electrode and the second electrode are electrically insulated, and a predetermined buffer voltage is applied to the second electrode with reference to a voltage of the first electrode.

12. The charged particle beam device according to claim 10, wherein
the first electrode is an extraction electrode that extracts charged particles from the charged particle source.

13. The charged particle beam device according to claim 10, wherein
a material of the first electrode is a magnetic material, and a material of the second electrode is a non-magnetic material.
